(19) United States
(12) Patent Application Publication
(10) Pub. No.: US 2004/0228431 A1
(43) Pub. Date: Nov. 18, 2004

(54) Method and device for generating a system clock

(75) Inventors: Ronalf Kramer, Munchen (DE); Stefan Honken, Munchen (DE)

Correspondence Address: Maginot, Moore & Beck, Bank One Tower, Suite 3000, 111 Monument Circle, Indianapolis, IN, 46204, US

(73) Assignee: Infineon Technologies AG, Munchen (DE)

(21) Appl. No.: 10/778,609

(22) Filed: Feb. 13, 2004

(30) Foreign Application Priority Data
Feb. 14, 2003 (DE) 103 06 313.7

(51) Int. Cl. H03D 3/24

(52) U.S. Cl. 375/376

(57) ABSTRACT

A method and a device are presented for generating a system clock (OC) of a transmitting and/or receiving device with the aid of a system oscillator (1, 2). At least one control signal (PS, FS, JS, IS) is thereby evaluated by an evaluation unit (12) and the system oscillator (1, 11) is actuated as a function of this control signal (PS, FS, JS, IS) in order to change its frequency. This makes it possible for problems which arise due to an excessive frequency tolerance of an oscillating quartz element (1) to be eliminated or avoided by preventive means.

The present invention relates to a method and a device for generating a system clock of a transmitting and/or receiving device with the aid of a system oscillator. In particular, it relates to a method and a device respectively in which the system oscillator is a quartz oscillator.

Digital transmitting or receiving devices for transmitting or receiving signals over data lines usually contain an oscillator which is used as a frequency standard.

In this situation, a quartz oscillator is generally used.

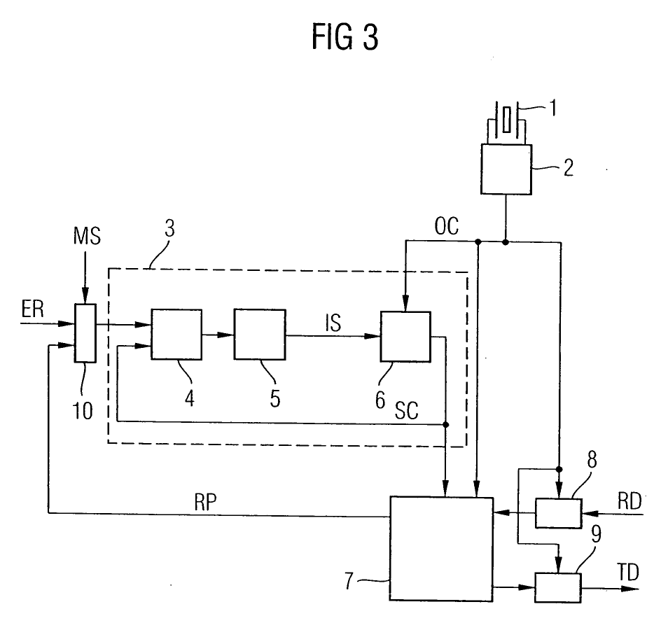

FIG. 3 shows a conventional digital signal processing system, which can be used as both a transmitting and receiving device. An analog data signal RD which is received is in this case converted by an analog-digital converter 8 into a digital signal, which is processed by a receiver part of a digital signal processor (DSP) 7. Correspondingly, the transmitter part of the digital signal processor 7 transmits digital data which is converted by a digital-analog converter 9 into a transmitting signal TD. The analog-digital and digital-analog conversions are effected in this case with a system clock OC, generated by a system oscillator 1, 2. The digital system processor 7 also uses this system clock. The system clock OC is generated by a system oscillator, which comprises an oscillating quartz element 1 and an oscillator unit 2 for the conversion of the mechanical oscillations of the oscillating quartz element into the system clock OC.

In addition to this, a symbol clock SC, generated by means of a phase locked loop 3 (PLL), is conducted to the digital signal processor 7 for the transmitting or receiving of data. The phase locked loop 3 thereby consists of a phase detector 4, a filter 5, and an oscillator 6. The oscillator 6 can, for example, be a numerically-controlled oscillator, of which the output frequency is unambiguously determined by a digital value of the control signal IF conducted to it, which in this case is an increment signal, and by the frequency of the system oscillator. As a reference clock for the phase locked loop, either an external reference clock ER or a phase RP from input data symbols is drawn upon. In the former case, the processing system is a clock master, because the transmitting symbols are sent at a clock which is determined by the external reference ER. An example of this is the COT side of an XDSL system (COT: Central Office Terminal, DSL: Digital Subscriber Line). In the latter case, the processing system is a clock slave, because the received data is drawn upon for generating the symbol clock. An example of this is, accordingly, the RT side of an XDSL system (RT: Remote Terminal). The switchover between operation as a clock master and clock slave can be effected as a function of a master/slave signal MS, which is conducted to a switching unit 10.

The function of the phase locked loop 3 and of the algorithms used in the digital signal processor 7 depends on the quartz frequency, since this is used as the frequency standard. In addition to the basic tolerance of the quartz frequency (when issued at room temperature), further tolerances come into being as a result of temperature changes, for example, and in particular as a result of ageing. These can also be added up in such a way that the tolerance which is permissible for the system as a whole is exceeded, and the system does not work properly. In this situation, the frequency offset or the frequency displacement of the oscillating quartz element can be so great, for example, that the frequency value which can be represented by the phase locked loop 3 will be exceeded. Accordingly, the phase locked loop 3 cannot provide the desired symbol clock SC. With the digital signal processor 7, the receiving symbol clock regulation is particularly dependent on the frequency of the oscillating quartz element. If the frequency displacement of the oscillating quartz element is too great, the situation may arise in which this regulating process no longer works correctly, and therefore data can no longer be correctly received.

A further problem lies in the fact that, at certain quartz frequencies and under certain circumstances, this receiving symbol clock regulation does not engage, or only with difficulty.

In order to resolve this problem, conventionally either quartz elements with low tolerance are used, and in particular with low ageing tolerance; these quartz elements, however, are relatively expensive. As an alternative, the signal processing system, and in particular the algorithms, of the digital signal processor are designed for higher tolerances of the quartz clock. This is associated with high expense and effort, and in part can only be achieved with difficulty.

One object of the present invention is therefore to provide a method and a device with which quartz elements with higher tolerances can be used for generating a system clock, but reliable operation will nevertheless be ensured.

This object is achieved by a method according to claim 1 and a transmitting and receiving device according to claim 22 respectively. The dependent sub-claims define preferred or advantageous embodiments of the invention.

According to the invention, it is proposed that at least one monitoring or control signal, which is present in a transmitting and/or receiving device, is evaluated, and a system oscillator, which generates a system clock as a function of the at least one control signal, is actuated in order to change its frequency. Preferably, a quartz oscillator is thereby used as the system oscillator. The change of frequency of the system oscillator can be effected, for example, by changing a capacitance coupled to the system oscillator.

The control signal thereby comprises in particular signals which indicate whether parts of the transmitting and/or receiving device are working correctly. For example, the control signal may comprise a lock-in signal which can be evaluated in order to determine whether a phase locked loop of the transmitting and/or receiving device is locked in at a specific frequency of the system oscillator. If this is not the case, the system oscillator will be actuated in order to change its frequency.

In addition to this, the control signal may comprise an algorithm signal, which indicates whether algorithms of a digital signal processor of the transmitting and/or receiving device are working correctly. If this is not the case, the system oscillator will in turn be actuated in order to change its frequency.

Such an algorithm signal can be generated, for example, by a check on the temporal run-up behaviour of an algorithm, by monitoring the quality of a signal derived from a received signal, or by monitoring the receiving symbol clock regulation of the digital signal processor.

If the system oscillator was used to change a frequency, such that the phase locked loop and/or the algorithms of the digital signal processor are working correctly, the value necessary for this can be stored in order to make use of it at a renewed activation or use of the transmitting and/or receiving device.

In addition to this, in the event of a receiving algorithm failing to run up, or scarcely doing so, the frequency of the oscillator can be altered in such a way that the receiving algorithm can run up. The term “run up” is understood to mean that the receiving algorithm adjusts itself to the data which is to be received.

In addition to this, if a reference frequency of the system oscillator is known, then, by evaluating the control signal, the frequency displacement of the system oscillator can be determined and the system oscillator actuated in order to compensate for this frequency displacement. This means, for example, that ageing tolerances can be compensated for, and an error function of elements or parts of the transmitting and/or receiving device can be preventively avoided.

The invention is explained in greater detail hereinafter by reference to the appended drawings on the basis of preferred embodiments. The drawings show:

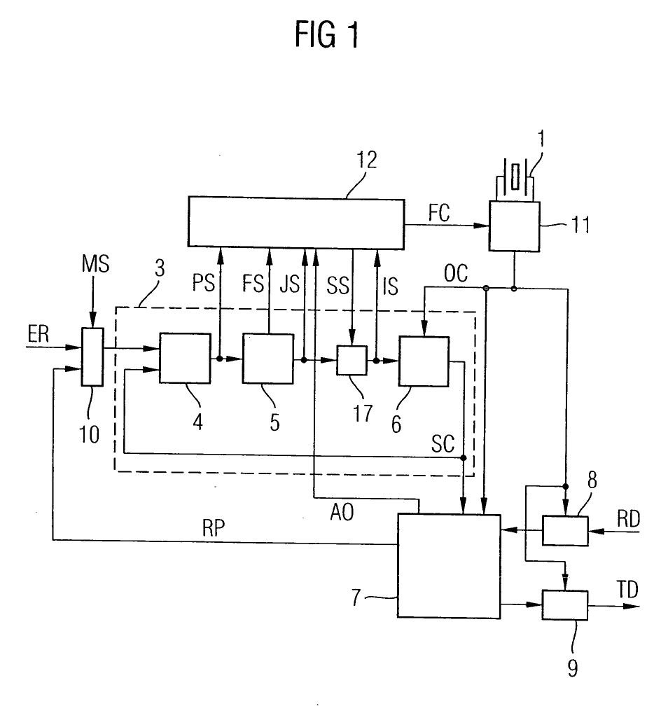

FIG. 1: An embodiment according to the invention of a transmitting and receiving device,

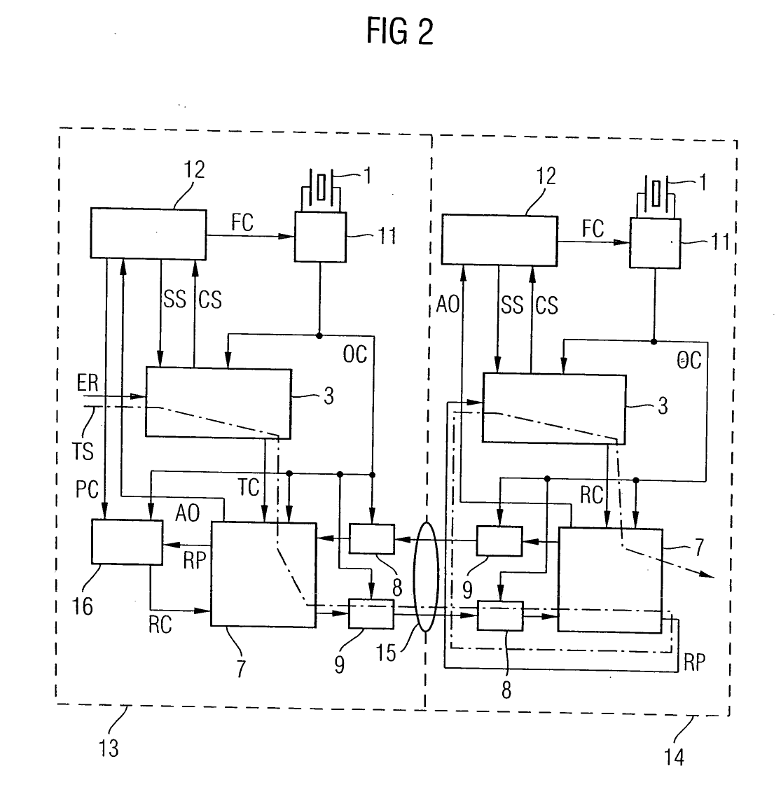

FIG. 2: A communications system with two transmitting and receiving devices according to the invention, and

FIG. 3: A transmitting and receiving device according to the prior art.

FIG. 1 represents an embodiment according to the invention of a combined transmitting and receiving device.

In the device according to the invention, analog receiving data RD is digitalized by an analog-digital converter 8 and further processed by a receiving part of a digital signal processor 7. Likewise, a transmitting part of the digital signal processor 7 sends data, which is converted by a digital-analog converter 9 into analog transmission data TD. The digital-analog and analog-digital conversion is effected in this case with a clock OC, which is also used by the digital signal processor. This system clock OC is generated by a system oscillator 1, 11. This consists of an oscillating quartz element 1 and an oscillator control unit 11. This oscillator control unit 11 can be actuated with a frequency control signal FC, in order to change the frequency of the oscillating quartz element 1 and therefore the system clock OC. This can be done, for example, by changing a capacitance, capable of being changed and coupled to the oscillating quartz element 1, in the oscillator control unit 11. The oscillator control unit 11 can thereby be integrated on a chip.

In addition to this, a symbol clock SC is conducted to the digital signal processor, which is generated by a phase locked loop 3 (PLL). This phase locked loop 3 consists of a phase detector 4, a filter 5, an adder 17, and a numerically-controlled oscillator 6. It is also possible in principle, however, for other oscillators to be used, such as, for example, voltage-controlled oscillators. With the adder 17, a first increment signal JS can be raised or lowered to a second increment signal IS. The frequency of the numerically-controlled oscillator 6 is unambiguously determined by the system clock OC and a digital value of the second increment signal IS. As a reference for the phase locked loop, either an external reference clock ER or the phase of the input data symbols RP can be drawn upon. In the former case, the transmitting and receiving device is a clock master, and in the latter case a clock slave. It is possible to switch between these two operating modes by means of a switchover unit 10, to which a master/slave switchover signal MS can be conducted.

In addition to this, an evaluation unit 12 is present, which receives control signals AO, PS, FS, JS and IS. In addition to this, the evaluation unit 12 can actuate the adder 17 by a control signal SS. The significances of the various different control signals will be further explained hereinafter.

The evaluation unit 12 evaluates the control signals and controls the oscillator control unit 11 to change the frequency of the system oscillator as a function of the control signals.

A number of different situations are described hereinafter in which the evaluation unit 12 actuates the system oscillator 1, 11, in order to change a frequency.

During the operation of the transmitting and receiving device according to the invention, the situation may arise in which a frequency displacement of the oscillating quartz element 1 is so great that the frequency value which can be represented to the filter 5 of the phase locked loop and which can therefore be represented by means of the increment signal IS, is permanently exceeded or exceeded in broad sections of the lock-in process. The term “frequency displacement” is understood in this situation to mean the difference between an actual frequency of the oscillating quartz element and a reference frequency.

By means of the control signals PS, FS, JS and IS, the evaluation unit can determine such a situation. This can be done by monitoring the phase signal PS, which indicates a phase difference by observation of the increment signal before (JS) or after (IS) the adder and/or by observation of the filter signal FS, which describes an integral portion of the filter 5. In the event of the phase locked loop never locking in, the phase difference acquires, for example, a final value. The value of the increment signal IS is then in general in the vicinity of the maximum or minimum value which can be represented.

If such a situation is determined, the evaluation unit actuates the system oscillator 1, 11, to change the frequency of the oscillating quartz element 1, until the phase locked loop locks in and the value of the increment signal IS lies within the range which can be represented.

As an additional measure, the evaluation unit can actuate the adder 17 in such a way that the value of the increment signal IS is changed in such a way that the phase locked loop locks in and the value of the increment signal IS lies within the range which can be represented.

This control procedure can also be effected in several steps.

If the frequency displacement of the oscillating quartz element 1 becomes too great, it may further arise that algorithms of the digital signal processor 7 will no longer work correctly. In this case, particular mention needs to be made of a receiving symbol clock regulation arrangement. In order to alleviate such a situation, an algorithm signal AO is conducted to the evaluation unit 12, which indicates whether the algorithms are working correctly.

There are several possibilities for generating this algorithm signal. For example, a temporal run-up behaviour of the algorithms of the digital signal processor 7 can be monitored. When the algorithm signal AO indicates that the algorithms are not working correctly, the evaluation unit 12 controls the system oscillator so as to change its frequency, and then, for example, a renewed run-up attempt takes place. If the run-up of the individual algorithms in each case is successful, the value of the signal FC, or, respectively, the required frequency change of the system oscillator, can be stored. This control information can then be used in a following activation or use of the transmitting and receiving device.

A further possibility for generating the algorithm signal is, for example, monitoring the quality of a receiving signal behind an equalizer in the digital signal processor. If this signal quality is too poor, this is an indication of algorithms not working correctly.

FIG. 2 shows a transmitting system with two transmitting and receiving devices 13 and 14 according to the invention connected by means of a transmission path 15. In this situation, the transmitting and receiving device 13 is designed as a clock master and the transmitting and receiving device 14 as a clock slave. The structure of the two transmitting and receiving devices 13 and 14 thereby corresponds essentially to the transmitting and receiving device represented in FIG. 1. The signals PS, FS, JS and IS from FIG. 1 are represented by one single control signal CS.

An external reference value clock ER is conducted to the transmitting and receiving device 13. The phase locked loop 3 of the transmitting and receiving device 13 produces from this a transmitting symbol clock TC, with which signals are sent to the transmitting and receiving device 14. From these signals the digital signal processor 7 of the transmitting and receiving device 14 obtains a receiving scanning phase RP. This serves as a reference for the phase locked loop 3 of the transmitting and receiving device 14 for generating a receiving symbol clock RC. By means of this recovery of the receiving symbol clock, the digital signal processor 7 of the transmitting and receiving device 14 also indirectly obtains the external reference clock ER. This path of the external reference clock is represented in FIG. 2 by a broken line, which is marked with the reference symbol TS. In addition, this clock from the transmitting and receiving device 14 can be used again for transmitting data to the transmitting and receiving device 13.

Accordingly, all the signals in the transmitting system are sent or received with a symbol clock derived from the external reference clock ER.

Even if no frequency displacement of the oscillating quartz element 1 pertains, or very little, it is possible that problems may arise with such an arrangement both in the clock master 13 and in the clock slave 14. Specifically, this may lead, under certain circumstances, to an unfavourable scanning phase at the beginning of a run-up of receiving algorithms, if the oscillating quartz element 1 has a frequency or phase which is unfavourable for the run-up procedure. This can make a reliable run-up of the system difficult, or prevent it entirely, on the clock master side as well as on the task slave side.

To resolve this problem, in the case of a clock slave (remote terminal/RT side) the system oscillator 1, 11, is actuated to achieve the defined change of frequency of the oscillating quartz element 1. This therefore ensures that, at the start of a run-up procedure, all the scanning phases will be covered. The change of frequency or detuning to be carried out in this case depends on the individual specific embodiment of the receiving regulating algorithms.

Because the actual frequency displacement depends on the oscillating quartz element of the clock slave, and is therefore not known at the first activation of the transmitting and/or receiving device, this procedure of changing this frequency or frequency detuning must, under certain circumstances, be repeated several times until the system has run up. In order to indicate that the system has run up, the algorithm signal AO can again be used.

Once the system has run up, an integral portion of the filter 5 of the phase locked loop, which can be determined by the evaluation unit 12 from the filter signal FS, makes it possible to draw a conclusion regarding the actual oscillating quartz frequency. For following uses of the transmitting and/or receiving unit as a clock slave, it is possible with this knowledge for the most favourable detuning to be precisely pre-set. How precisely also depends on the tolerance of the external reference clock ER on the corresponding clock master side.

On the clock master side, a problem of this nature arises in general with a possibly unfavourable receiving symbol scanning phase at the start of a run-up procedure. The reason for this is that, as explained heretofore, the transmitting symbol clock frequency of the clock slave side is regulated to the receiving symbol clock frequency of the clock slave side. Accordingly, the receiving symbol clock frequency of the clock master side 13 corresponds to the transmitting symbol clock frequency on the clock master side 13. The frequency displacement between the clock master transmitting symbol clock and the unregulated clock master receiving symbol clock, which is derived directly from the clock of the system oscillator on the clock master side, is represented by an integral portion of a filter of the phase locked loop 16 for reference clock synchronisation on the clock master side. The start scanning phase in this case depends essentially on the line length of the transmission medium 15.

On the clock master side, a specific run-through of the scanning phase can be induced, by an integral portion of a filter (PI filter) of the phase locked loop 3 on the clock master 13 side for regulating the receiving symbol clock being set to a specific value. By means of this, a defined detuning of the receiving symbol frequency is derived. This specific frequency detuning is likewise carried out by the evaluation unit 12 on the clock master side. For precise adjustment it is possible in this case for the integral portion of the filter of the phase locked loop 16 to be drawn upon for the reference clock synchronisation.

Hereinafter preventive measures are also explained to compensate, for example, for ageing effects.

The frequency of the external reference clock ER is in general substantially more precise than the tolerances of the oscillating quartz elements 1 of the two transmitting and receiving devices 13 and 14. This frequency of the external reference clock ER is in general also precisely known.

Accordingly, the evaluation unit 12 of the transmitting and receiving device 13 can determine, from the increment signal IF, with which an oscillator such as a numerically-controlled oscillator, of the phase locked loop 3 is actuated, a frequency deviation of the oscillating quartz element 1 from its nominal frequency (actual frequency). In the event of this exceeding a specific value, then, at the start of the next use, the oscillator control unit 2 will be actuated to change the frequency of the oscillating quartz element 1 in order to compensate for this deviation. In this way, long-term tolerances of the oscillating quartz element 1 are compensated for. Accordingly, incorrect behaviour of the clock master 13, or even its total failure, can be avoided by preventive measures. The value of the control signal FC which is needed for this is thereby stored in each case, in order for it to be used again at the next use or activation of the transmitting and receiving device. It is also possible for this value to be given to a further device or a higher layer, so that a continuous monitoring of the quartz frequency can be carried out.

Since, as explained heretofore, the transmitting and receiving device 14, the clock slave, also receives the frequency of the external reference clock ER by way of the receiving symbol clock recovery, it is also possible in the same way for a deviation in the frequency of the oscillating quartz element 1 from its nominal value to be detected and corrected accordingly. The measures in the slave and in the master are thereby independent of one another.

An example is given hereinafter of such a regulating arrangement for the frequency of the oscillating quartz element. In this situation, fsym signifies a symbol frequency, fq the frequency of the oscillating quartz element, and fr the frequency of the external reference clock ER. All the nominal values are additionally designated by nom, such as frnom, for example. Relative tolerances are designated by Δ, e.g.

Δfr=(fr−frnom)/frnom.

With oscillated-in or locked-in phase locked loops, fsym=fr applies. The increment incr of the increment signal IS for a numerically-controlled oscillator 6 with a bit width n then amounts to:

incr=2″×fr/fq.

If the tolerances are incorporated, this gives

incr=2″×(frnom/fqnom)×(1+Δfr)/(1+Δfq)

If 1/(1+x)=1−x is approximated for x<<1 and if Δfq×Δfr is disregarded, then there is derived:

incr=2″×(frnom/fqnom)×(1+Δfr˜Δfq)

or

Δincr=Δfr˜Δfq.

At the deviation of the increment value it is therefore possible to identify the deviation of the frequency of the oscillating quartz element, albeit distorted by Δft.

Δfr is, however, in general a relatively small value.

A detuning of the quartz element by the value Δfq=−Δfr can be carried out, for example, if |Δincr|>2×Δfr, since the deviation of the frequency of the oscillating quartz element lies in the range −Δfr<fq<3×Δfr.

As standard, |Δfr|<32 ppm is indicated for an sDSL system. A quartz oscillator element integrated in a chip can be changed in its frequency by the switching in or out of chip-internal capacitances, typically by ±100 ppm.

As an algorithm signal AO, use may be made, for example, of that period of time which is required for the “training” of the digital signal processor when the device is started. If a predetermined period of time is exceeded, but the system is still running up, it is possible, at the start of the next use, to detune the oscillating quartz element in accordance with the value and the sign of Δincr. The evaluation unit 12 is in this case preferably realised by software, for example as a part of the overall software which controls the digital signal processor.

By means of the transmitting and receiving device presented, and the method presented, it is possible for quartz elements with higher basic tolerance and ageing tolerance to be used, which offers substantial price advantages. In addition to this, it is possible, for example, in various different xDSL systems, for the exceeding of the run-up time of algorithms of the digital signal processor to be avoided, or for a reliable run-up of the receiving symbol clock regulation to be incurred, since these procedures are influenced by the tolerance of the frequency of the oscillating quartz element.

It is of course also possible for only some of the mechanisms presented for the control or regulation of the frequency of the oscillating quartz element to be used. In addition to this, these mechanisms can also be used in pure transmitting or pure receiving devices.

1-35. (canceled)

36. A communications device comprising:
an oscillator with a controllable output frequency;
a phase locked loop operably connected to receive the controllable output frequency of the oscillator, the phase locked loop generating a clock output based upon the controllable output frequency and generating at least one condition signal output indicative of a condition within the phase locked loop; and
an evaluation unit operably connected to the phase locked loop to receive the at least one condition signal and operably connected to the oscillator to control the output frequency of the oscillator based upon the at least one condition signal.

37. The device of claim 36, wherein the at least one condition signal comprises a signal used within the phase locked loop.

38. The device of claim 37, wherein the phase locked loop comprises:
a phase detector operable to detect a phase difference between a first and a second signal and to generate a signal indicative of a detected phase difference between the first and the second signal, and wherein the at least one condition signal comprises the signal indicative of a detected phase difference.

39. The device of claim 38, wherein the first signal comprises a signal received by the communications device from another communications device and wherein the second signal comprises the controllable output frequency of the oscillator.

40. The device of claim 37, wherein the phase locked loop comprises a filter operable to generate a correction signal based upon a phase difference between a first and a second signal, and wherein the at least one condition signal comprises the correction signal.

41. The device of claim 37 wherein the phase locked loop comprises an adder operable to change a correction signal generated based upon a phase difference between a first and a second signal, and wherein the at least one condition signal comprises the changed correction signal.

42. The device of claim 36, wherein the phase locked loop comprises a filter having an integral portion and operable to generate a correction signal based upon a phase difference between a first and a second signal, and wherein the at least one condition signal comprises a signal indicative of the integral portion of the filter.

43. The device of claim 36, wherein the device further comprises:
a digital signal processor having at least one algorithm used to detect a signal, the processor operable to generate at least one signal indicative of the efficacy of the at least one algorithm, and wherein the evaluation unit is further operably connected to the processor to receive the at least one efficacy signal, the evaluation unit operable to control the output frequency of the oscillator based upon the at least one efficacy signal.

44. The device of claim 43, wherein the at least one efficacy signal is indicative of the algorithm's run-up behavior.

45. The device of claim 43, wherein the at least one efficacy signal is indicative of the received signal strength of a received signal.

46. The device of claim 43, wherein the phase locked loop comprises:
a phase detector operable to detect a phase difference between a first and a second signal and to generate a phase difference signal indicative of the detected phase difference between the first and the second signal;
a filter having an integral portion, operably connected to the phase detector to receive the phase difference signal and operable to generate a signal indicative of the integral portion and to generate a correction signal based upon the phase difference signal; and
an adder operably connected to the filter to receive the correction signal and operable to generate a changed correction signal based upon the correction signal, and wherein the at least one condition signal comprises:
the phase difference signal;
the correction signal;
the changed correction signal; and
the signal indicative of the integral portion of the filter.

47. The device of claim 36, wherein the device comprises a variable capacitance provided by at least one capacitor operably connected to the oscillator and the evaluation unit, and wherein the evaluation unit controls the output frequency of the oscillator by controlling the variable capacitance.

48. A communications device comprising:
an oscillator with an output frequency;
a variable capacitance comprising at least one capacitor configured to be operably connected to the oscillator such that when the capacitance operably connected to the oscillator changes the output frequency of the oscillator; and
an evaluation unit operably configured to evaluate a signal indicative of at least one condition within the communications device, and operably connected to the variable capacitance to control variation of the capacitance based upon the at least one condition within the communications device.

49. The device of claim 48, wherein the at least one capacitor comprises:
a plurality if capacitors, each of the plurality of capacitors configured such that when each of the plurality of capacitors is not operably connected to the oscillator, each of the plurality of capacitors can be switched into operable connection with the oscillator to increase capacitance and such that when each of the plurality of capacitors is operably connected to the oscillator, each of the plurality of capacitors can be switched out of operable connection with the oscillator to decrease capacitance.

50. The device of claim 48, further comprising:
a phase locked loop operably connected to receive the output frequency of the oscillator, the phase locked loop generating a clock output based upon the output frequency and generating at least one condition signal indicative of a condition within the phase locked loop, and wherein the signal indicative of at least one condition within the communications device evaluated by the evaluation unit comprises the at least one condition signal indicative of a condition within the phase locked loop.

51. The device of claim 50, wherein the at least one condition signal comprises a signal used within the phase locked loop.

52. The device of claim 51, wherein the phase locked loop comprises:
a phase detector operable to detect a phase difference between a first and a second signal and to generate a signal indicative of the detected phase difference between the first and the second signal, and wherein the at least one condition signal used within the phase locked loop comprises the signal indicative of a detected phase difference.

53. The device of claim 51, wherein the phase locked loop comprises a filter operable to generate a correction signal based upon a phase difference between a first and a second signal, and wherein the at least one condition signal is the correction signal.

54. The device of claim 48, wherein the device further comprises:
a digital signal processor having at least one algorithm used to detect a signal, the processor operable to generate at least one signal indicative of the efficacy of the at least one algorithm, and wherein the evaluation unit is further operably connected to the processor to receive the at least one efficacy signal, the evaluation unit operable to control the output frequency of the oscillator based upon the at least one efficacy signal.

55. The device of claim 54, wherein the at least one efficacy signal is indicative of the processor run-up behavior.

56. The device of claim 54, wherein the at least one efficacy signal is indicative of the received signal strength of a received signal.

57. The device of claim 48 wherein the device comprises:
a chip, and wherein the variable capacitance comprises:
a plurality of capacitors within the chip, and wherein the evaluation unit is operably configured to switch each of the plurality of capacitors into and out of operable connection with the oscillator.

58. A method of generating a clock signal in a communications device having an oscillator, a phase locked loop, a digital signal processor and an evaluation unit, comprising the steps of:
generating with the oscillator a generated output frequency;
generating with the phase locked loop a first clock using the first generated output frequency;
generating a control signal based upon the condition of at least one part within the device, wherein the part is selected from the group consisting of phase locked loop parts and the digital signal processor;
evaluating with the evaluation unit the control signal against a predetermined control signal value; and
controlling the oscillator to change the output frequency generated by the oscillator based upon the evaluation.

59. The method of claim 58, wherein the step of generating comprises the step of generating a control signal based upon the efficacy of the run-up behavior of the digital signal processor.

60. The method of claim 58, wherein the step of generating a control signal comprises the step of:
generating a signal indicative of a condition within the phase locked loop, and wherein the step of evaluating comprises the step of:
evaluating with the evaluation unit the signal indicative of a condition against a predetermined signal value.

61. The method of claim 60, wherein the step of generating the first clock comprises the step of:
detecting a phase difference between a first and a second signal, and wherein the step of generating a signal indicative of a condition comprises the step of:
generating a signal indicative of the detected phase difference.

62. The method of claim 60, wherein the step of generating the first clock comprises the step of:
generating a correction signal based upon a phase difference between a first and a second signal, and wherein the step of generating a signal indicative of a condition comprises the step of:
generating the correction signal.

63. The method of claim 60, wherein the phase locked loop comprises a filter with an integral portion and wherein the step of generating a signal indicative of a condition within the phase locked loop comprises the step of:
generating a signal indicative of the integral portion of the filter within the phase locked loop.

64. The method of claim 60, wherein the digital signal processor comprises at least one algorithm used to detect a signal, the method further comprising the steps of:
generating a signal indicative of the efficacy of the at least one algorithm;
evaluating with the evaluation unit the efficacy signal; and
controlling the oscillator to change the frequency generated by the oscillator based upon the evaluation.

65. The method of claim 64, wherein the efficacy signal is indicative of the processor run-up behavior, and wherein the evaluating step further comprises the step of:
evaluating the run-up signal, and wherein the controlling step comprises the step of:
controlling the oscillator to change the frequency generated by the oscillator based upon the evaluation.

66. The method of claim 64, wherein the at least one efficacy signal is indicative of the received signal strength of a received signal, and wherein the step of evaluation further comprises the step of:
evaluating the signal indicative of the received signal strength, and wherein the controlling step comprises the step of:
controlling the oscillator to change the frequency generated by the oscillator based upon the evaluation.

67. The method of claim 60, wherein the device comprises a variable capacitance provided by at least one capacitor operably connected to the oscillator and the evaluation unit, and wherein the step of controlling comprises the step of:
controlling the variable capacitance to change the frequency generated by the oscillator.

68. The method of claim 67, wherein the step of controlling comprises at least one of the steps of:
switching a capacitor into operable connection with the oscillator; and
switching a capacitor out of operable connection with the oscillator.

69. A method of controlling the frequency of an oscillator within a communications device having a plurality of switchable capacitors providing a variable capacitance affecting the frequency of the oscillator, and a digital signal processor using at least one algorithm to process a signal detected by the communications device, the method comprising the steps of:
outputting with the oscillator an output frequency;
modifying the operation of the processor based upon the at least one algorithm;
generating an efficacy signal indicative of the efficacy of the algorithm in modifying the operation of the processor; and
evaluating the efficacy signal, the method further comprising at least one of the steps of:
switching in capacitors to increase the capacitance; and
switching out capacitors to decrease the capacitance
